(19) United States
(12) Patent Application Publication
(10) Pub. No.: US 2025/0358930 A1
(43) Pub. Date: Nov. 20, 2025

(54) STRETCHABLE DEVICE

(71) Applicant: Murata Manufacturing Co., Ltd., Nagaokakyo-shi (JP)

(72) Inventors: Kazuhiro ISEBO, Nagaokakyo-shi (JP); Hayato Katsu, Nagaokakyo-shi (JP)

(21) Appl. No.: 19/283,611

(22) Filed: Jul. 29, 2025

Related U.S. Application Data
(63) Continuation of application No. PCT/JP2024/013133, filed on Mar. 29, 2024.

(30) Foreign Application Priority Data
Apr. 11, 2023 (JP) 2023-064412

(51) Int. Cl. H05K 1/02; H05K 1/11

(52) U.S. Cl. CPC H05K 1/0283; H05K 1/115

(57) ABSTRACT

A stretchable device including: a laminated body having a plurality of stretchable substrates; and a stretchable wiring arranged inside the laminated body. The stretchable wiring includes two wiring main surfaces facing each other in a lamination direction of the stretchable substrate. In a sectional view, at least one of the wiring main surfaces includes a first region and a second region. The first region is a region in which a part of the wiring main surface is raised in the lamination direction more than that of the second region.

### CROSS REFERENCE TO RELATED APPLICATIONS

The present application is a continuation of International application No. PCT/JP2024/013133, filed Mar. 29, 2024, which claims priority to Japanese Patent Application No. 2023-064412, filed Apr. 11, 2023, the entire contents of each of which are incorporated herein by reference.

### TECHNICAL FIELD

The present disclosure relates to a stretchable device.

### BACKGROUND ART

Conventionally, a stretchable device in which a stretchable wiring is mounted on a stretchable substrate has been known. This stretchable device can be used by being attached to a human body.

Patent Document 1 describes a stretchable device having a multilayer structure in which a plurality of stretchable substrates are laminated, and a stretchable wiring is arranged on a main surface of the stretchable substrate.
Patent Document 1: Japanese Patent No. 6823472

### SUMMARY OF THE DISCLOSURE

In the stretchable device of Patent Document 1, at least one stretchable wiring is provided on each of two opposing main surfaces of a plurality of stretchable substrates. A plurality of stretchable substrates including a stretchable wiring are stacked together with an interlayer stretchable substrate such that at least a part of the stretchable wiring provided on each main surface is in contact with one another, and are pressure-bonded.

The inventor of the present application has noticed that there is a problem to be overcome in the stretchable device as described above, and has newly found a need to take measures against the problem. Specifically, a problem below has been found.

In general, a stretchable wiring applied to a stretchable device is required to have small thickness in order to obtain excellent stretchability. In particular, in the stretchable device having the laminated structure as described above, height of the device is required to be further reduced from the viewpoint of stretchability and wearing feeling, and thus thickness of the stretchable wiring is desirably small. However, in the stretchable wiring having small thickness, damage such as a crack and disconnection is likely to occur in the stretchable wiring due to stress generated by expansion and contraction of the stretchable device, and there is a possibility that reliability of the stretchable device is deteriorated.

The present disclosure has been made in view of such a problem. That is, a main object of the present disclosure is to provide a stretchable device having more suitable reliability also in a case where the stretchable device has a laminated structure.

To achieve the above object, in an embodiment of the present disclosure, there is provided a stretchable device that includes: a laminated body comprising a plurality of stretchable substrates; and a stretchable wiring arranged inside the laminated body, in which the stretchable wiring includes two wiring main surfaces facing each other in a lamination direction of the stretchable substrate, at least one of the wiring main surfaces includes a first region and a second region in a sectional view of the stretchable device, and the first region is a region in which a part of the wiring main surface is raised in the lamination direction more than that of the second region.

The stretchable device according to an embodiment of the present disclosure has more suitable reliability also in a case of having a laminated structure.

### BRIEF EXPLANATION OF THE DRAWINGS

FIG. 1 is a schematic plan view of a stretchable device according to a first embodiment of the present disclosure.

FIG. 2 is a sectional view taken along line A-A of the stretchable device illustrated in FIG. 1.

FIG. 3 is a schematic sectional view illustrating the stretchable device according to a variation of the first embodiment of the present disclosure.

FIG. 4A is a schematic plan view of a stretchable wiring according to various variations of the first embodiment of the present disclosure.

FIG. 4B is a schematic plan view of the stretchable wiring according to various variations of the first embodiment of the present disclosure.

FIG. 4C is a schematic plan view of the stretchable wiring according to various variations of the first embodiment of the present disclosure.

FIG. 4D is a schematic plan view of the stretchable wiring according to various variations of the first embodiment of the present disclosure.

FIG. 4E is a schematic plan view of the stretchable wiring according to various variations of the first embodiment of the present disclosure.

FIG. 5 is a schematic plan view of the stretchable device according to a second embodiment of the present disclosure.

FIG. 6 is a sectional view taken along line B-B of the stretchable device illustrated in FIG. 5.

FIG. 7 is a schematic sectional view for explaining a method of manufacturing the stretchable device of the present disclosure.

FIG. 8 is a schematic sectional view for explaining a method of manufacturing the stretchable device of the present disclosure.

FIG. 9A is a schematic sectional view of the stretchable device used as an example.

FIG. 9B is a schematic sectional view of the stretchable device used as a comparative example.

### DESCRIPTION OF THE PREFERRED EMBODIMENTS

Hereinafter, embodiments of the present disclosure will be described in detail with reference to the drawings. In each embodiment, a difference from the description before the embodiment will be mainly described. Particularly, similar functions and effects achieved by similar configurations will not be mentioned sequentially for each of the embodiments. Among constituent elements in the embodiments below, a constituent element not described in an independent claim will be described as an optional constituent element. Further, size and a ratio of size of constituent elements illustrated in the drawings are not necessarily strict. Further, in the drawings, substantially the same configurations are denoted by the same reference symbols, and redundant description may be omitted or simplified.

The term “sectional view” or “sectional view shape” referred to in the present description is based on a form captured from a direction substantially perpendicular to the thickness direction of the stretchable device (in short, a form obtained by cutting along a plane parallel to the thickness direction of the stretchable device). In a case where the stretchable device has a laminated structure including a plurality of stretchable substrates, the “sectional view” or “sectional view shape” is based on a form captured from a direction substantially perpendicular to the lamination direction of the stretchable substrates (in short, a form obtained by cutting along a plane parallel to the lamination direction). Further, the term “plan view” used in the present description is based on a layout diagram in a case where an object is viewed from the upper side or lower side along the thickness direction (or lamination direction) of the stretchable device.

Further, in the present description, “on” an element includes not only a case of being in contact with an upper surface of the element but also a case of not being in contact with the upper surface of the element. That is, “on” an element includes not only an upper position away from the element, that is, an upper position with another object on the element interposed between them or an upper position spaced apart from the element, but also a directly above position in contact with the element. Further, the term “on” does not necessarily mean the upper side in the vertical direction. The term “on” merely indicates a relative positional relationship of certain elements.

### First Embodiment

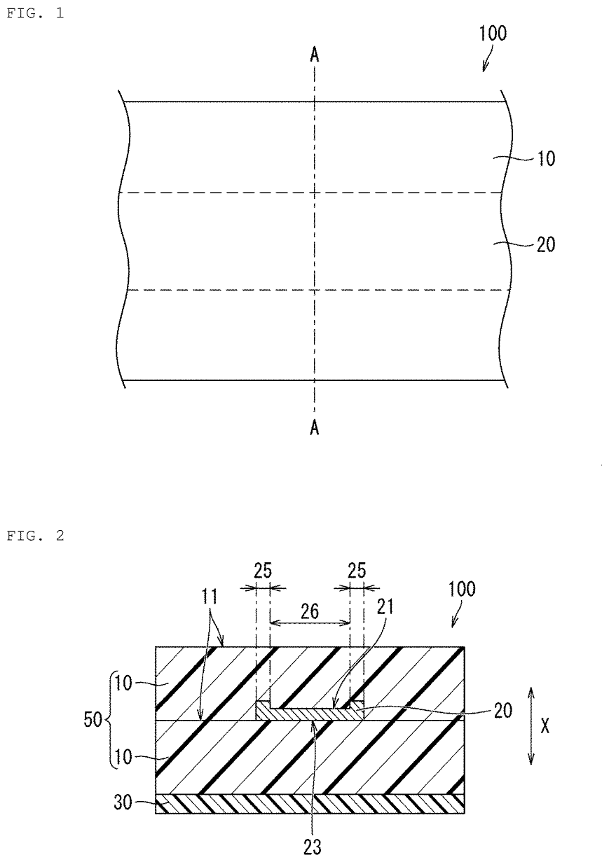

A structure of a stretchable device will be described with reference to FIGS. 1 and 2. FIG. 1 is a top view schematically illustrating a stretchable device 100 according to a first embodiment of the present disclosure. FIG. 2 is an A-A sectional view of the stretchable device 100 of FIG. 1. Note that a sectional view in the present description illustrates a section parallel to a thickness direction X of the stretchable device 100. In other words, the section is perpendicular to an extending direction of a stretchable wiring 20. Also in actual comparison, it can be confirmed by the above-described sectional view at an optional position of the stretchable wiring 20 extending in a certain direction.

In the stretchable device 100, the stretchable wiring 20 is routed on a main surface 11 of a stretchable substrate 10. Note that a shape of the stretchable device 100 is not particularly limited. Although only a wiring extending in a specific direction is illustrated in FIG. 1 for the sake of clarity, the stretchable wiring 20 may extend in any direction on the main surface 11 of a stretchable substrate. The stretchable wiring 20 may not be necessarily arranged linearly when viewed from the thickness direction X of the stretchable substrate 10, and may be arranged, for example, in a curved shape. Further, the stretchable wiring may not necessarily extend in one direction when viewed from the thickness direction X. The number of the stretchable wirings is also not particularly limited, and one or a plurality of wirings may be arranged.

The stretchable device 100 may mainly include the stretchable substrate 10 and the stretchable wiring 20 provided on a main surface of the stretchable substrate 10. Further, an adhesive layer 30 which contributes to mounting of the stretchable device 100 and can be attached to an adherend may be further provided.

Further, an “adherend” in the present description means a counterpart to which the stretchable device is attached, and can also be referred to as an adhesion target, attachment target, mounting target, or the like. For example, an adherend can be a living body.

Hereinafter, arrangement of these constituent elements will be described with reference to FIGS. 1 and 2. As illustrated in FIGS. 1 and 2, the stretchable wiring 20 is provided on the main surface 11 of the stretchable substrate, and the adhesive layer 30 is provided on a second main surface 12 side.

### (Stretchable Substrate 10)

The stretchable substrate 10 (hereinafter, also simply referred to as “substrate”) is a sheet-like or film-like stretchable substrate, and includes, for example, a resin material having stretchability. Here, the term “stretchability” in the present description means, in short, a property of being stretchable, and can also be referred to as stretching property, stretchable property, or the like. More specifically, it means a property of being capable of stretching from a non-stretched state, which is a normal state with no tensile stress applied, by applying tensile stress and capable of contracting when released from a stretched state. Examples of the resin material used as the stretchable substrate include thermoplastic polyurethane.

In an embodiment of the present disclosure, the stretchable substrates 10 are laminated on each other in the thickness direction. More specifically, a plurality of the stretchable substrates 10 may have a multilayer structure in which they are laminated so that their main surfaces face each other. That is, a plurality of the stretchable substrates 10 may form a laminated body 50 by being laminated in the thickness direction X of the stretchable substrate.

A plurality of the stretchable substrates 10 included in the laminated body 50 may have the same material, or the stretchable substrates 10 having different materials may be laminated. Further, a stretchable substrate located in an outermost layer of the laminated body 50 (for example, a stretchable substrate located farthest from the adhesive layer 30) also contributes to protection of the stretchable wiring 20 arranged inside the laminated body 50, and can be understood as a laminate layer, a cover layer, a protective layer, a coating layer, or the like.

Thickness of the stretchable substrate 10 is not particularly limited, but is preferably 1 mm or less, more preferably 100 μm or less, still more preferably 50 μm or less when emphasis is placed on not hindering stretching of a surface of an adherend 200 at the time of adhesion to an adherend such as a living body. Further, thickness of the stretchable substrate is preferably 1 μm or more. Further, a plurality of the stretchable substrates 10 included in the laminated body 50 do not necessarily have the same thickness. That is, a plurality of the stretchable substrates 10 may have different thicknesses, and for example, the configuration may be such that only an outermost layer has a different thickness.

### (Stretchable Wiring 20)

The stretchable wiring 20 (hereinafter, also simply referred to as “wiring”) contains a conductive particle and resin. Examples of the stretchable wiring 20 include a mixture containing metal powder of Ag (silver), Cu (copper), Ni (nickel), and the like as conductive particles, and elastomer-based resin, such as silicone resin. Average particle size of the conductive particles is not particularly limited, but is preferably 0.01 μm to 10 μm. Further, a shape of the conductive particle is preferably spherical.

In one embodiment, in a case where the stretchable device has a multilayer structure including the laminated body 50 formed by laminating a plurality of the stretchable substrates 10, the stretchable wiring 20 may be arranged inside the laminated body 50. More specifically, the stretchable wiring 20 may be positioned on a main surface of the stretchable substrate 10, and the stretchable substrates 10 may be laminated on each other such that the stretchable wiring 20 is positioned inside the laminated body 50. In other words, a plurality of the stretchable substrates 10 may be laminated with the stretchable wiring 20 interposed between them. In such a structure, it can also be understood that a plurality of the stretchable substrates 10 are laminated in such a manner that the stretchable wiring 20 arranged on a main surface of one of the stretchable substrates 10 is sandwiched by another one of the stretchable substrates 10. That is, a stretchable wiring may be sandwiched between the stretchable substrates 10 laminated to each other inside the laminated body 50 formed by laminating a plurality of the stretchable substrates 10.

### (Adhesive Layer 30)

The adhesive layer 30 has adhesiveness that allows the stretchable device 100 to be attached to an adherend. The adhesive layer 30 includes a substrate-side main surface located on the stretchable substrate 10 side and an adherend-side main surface located on the adherend side. It can be understood that the substrate-side main surface is a main surface located on the inner side of the stretchable device 100, and the adherend-side main surface is a main surface located on the opposite side of the substrate-side main surface and located on the outer side of the stretchable device 100. The stretchable device 100 is mounted so as to be joined to an adherend on the adherend-side main surface of the adhesive layer 30, and the adherend-side main surface can also be referred to as an attaching surface, an adhesive surface, a mounting surface, or the like. The adhesive layer 30 preferably has adhesiveness on both main surfaces. That is, the adhesive layer 30 may have adhesiveness not only on an attaching surface to an adherend but also on the substrate-side main surface.

The adhesive layer may be attached to an adherend on a main surface located on the side opposite to the stretchable substrate. In a case where an adherend is a living body, the adhesive layer 30 can be used without any particular limitation as long as it is an adhesive that is mild to the skin, has sufficient pressure-sensitive adhesiveness, and can be easily peeled off from the skin after use. Although it is mere exemplification, examples of the adhesive layer 30 include a synthetic rubber-based adhesive, an acryl-based adhesive, a urethane-based adhesive, a natural rubber-based adhesive, and/or a silicone-based adhesive, and a synthetic rubber-based adhesive is more preferable. Further, the adhesive layer 30 preferably has excellent stretchability and flexibility from the viewpoint of followability to a shape and movement of a surface of a living body.

### Characteristic Portion of First Embodiment

A characteristic portion of the first embodiment will be described below based on content of a main constituent element of the stretchable device described above. The stretchable wiring 20 includes a first wiring main surface 21 and a second wiring main surface 23, which are two wiring main surfaces facing each other in the lamination direction X of the stretchable substrate 10. Note that, in the present description, the lamination direction X corresponds to a thickness direction of the stretchable substrate/stretchable wiring. In the stretchable device of the present disclosure, the stretchable wiring 20 includes a first region 25 (hereinafter, also referred to as a raised region) in which a part of at least one of two wiring main surfaces is raised in the lamination direction X, and a second region 26 corresponding to a portion other than the first region 25. As illustrated in the diagram, the first region 25 is a region where a part of a wiring main surface is raised in the lamination direction X more than the second region 26.

The “first region (raised region)” in the present description means a region protruding in the lamination direction X with a different height as compared with a region (that is, the second region 26) other than the first region 25 on a wiring main surface in sectional view. That is, the stretchable wiring 20 means a region locally raised in the lamination direction X of the stretchable substrate 10 more than the second region 26. In other words, in sectional view, at least one wiring main surface of the stretchable wiring 20 is not a uniform plane, and includes the raised region 25 in which a part of a wiring main surface is raised in the lamination direction X. Note that, in the present description, “part of a wiring main surface” refers to a portion larger than 0% and equal to or less than 60% of a surface area of a wiring main surface when viewed from the lamination direction.

On the other hand, the second region 26 means a portion other than the first region 25 where a part of a wiring main surface is raised, and can also be referred to as a non-raised region, a main region of a wiring main surface, a base region, or the like. Alternatively, the second region 26 can be understood as a region having relatively reduced thickness or a region relatively recessed with respect to the raised first region 25.

With the structure including the raised region 25 on a wiring main surface, the stretchable wiring 20 may include two regions having different thicknesses from each other in sectional view. In the present description, the thickness direction coincides with the lamination direction. Thickness of the stretchable wiring 20 can also be referred to as a distance between the first wiring main surface 21 and the second wiring main surface 23 of the stretchable wiring 20. In sectional view, thickness T1 of a stretchable wiring in the first region 25 may be larger than thickness T2 of a stretchable wiring in the second region 26 (see FIG. 3). In other words, the stretchable wiring 20 may have smaller thickness in the second region 26 than in the first region 25. Therefore, it can be understood that a region where the stretchable wiring 20 is relatively thick in sectional view is the first region 25, and another region where the stretchable wiring 20 is relatively thin is the second region 26. For this reason, the first region 25 can also be referred to as a thick region, and the second region 26 can also be referred to as a thin region.

On a wiring main surface, the first region 25 and the second region 26 may be continuous with each other. In other words, a wiring main surface may be formed by a step surface extending over the first region 25 and the second region 26. In such a structure, it can also be understood that the first region 25 and the second region 26 are adjacent to each other. For example, as illustrated in FIG. 2, a wiring main surface may be formed by the second region 26 that is a flat surface extending substantially perpendicular to the lamination direction X and the first region 25 that is continuous with the second region 26 and raised in the lamination direction X with respect to the second region 26.

According to the stretchable device of the present disclosure, strength of the stretchable wiring 20 may be improved by increasing thickness of a part of the stretchable wiring 20 by the raised region 25. By this, occurrence and/or extension of a crack in the stretchable wiring 20 is suitably suppressed, and as a result, disconnection of the wiring 20 may be suitably suppressed. Therefore, the present disclosure may provide a highly reliable stretchable device capable of more suitably preventing damage to the stretchable wiring 20 at the time of use of the stretchable device.

Furthermore, the inventor of the present application has found that the structure including the raised region is suitable for suitably achieving both stretchability of the stretchable device and prevention of disconnection. In general, in order to prevent disconnection of the stretchable wiring, it may be conceived to increase thickness of the wiring, but increase in thickness of the wiring may be a factor of decrease in wearing feeling and/or stretchability of the stretchable device. According to the present disclosure, since thickness of the stretchable wiring 20 is locally increased in the raised region 25 without increase in thickness of the stretchable wiring 20 as a whole, it is possible to reduce decrease in wearing feeling and/or stretchability of the stretchable device. For this reason, the stretchable device of the present disclosure can realize suitable stretchability of the stretchable device while suppressing disconnection.

Further, in a stretchable device having a laminated structure, adhesion between a stretchable substrate and a stretchable wiring joined by pressure bonding may be relatively weak. For this reason, when a stretchable device is expanded and contracted, there is a possibility that interlayer peeling occurs between the stretchable substrate and the stretchable wiring that are joined by pressure bonding.

According to the present disclosure, since the stretchable wiring 20 includes the raised region 25 as described above, a contact area between the stretchable substrate 10 and the stretchable wiring 20 increases as compared with a case where the stretchable wiring 20 has a uniform surface (for example, a smooth flat surface or curved surface). For this reason, the stretchable substrate 10 and the stretchable wiring 20 can be joined over a larger area, and occurrence of peeling (what is called delamination) between the substrate 10 and the wiring 20 laminated and joined in close contact with each other can be suitably suppressed.

Furthermore, due to a difference in thickness between the first region 25 and the second region 26, an anchor effect may act in joining between the stretchable wiring 20 and the stretchable substrate 10. Due to this anchor effect, the wiring 20 and the substrate 10 can be more suitably brought into close contact with each other. For this reason, peeling resistance between the wiring 20 and the substrate 10 is further improved, and a more suitable stretchable device may be obtained in terms of reliability.

Preferably, the stretchable wiring 20 and the stretchable substrate 10 in contact with the stretchable wiring 20 are joined over the entire wiring main surface. That is, the stretchable wiring 20 may be joined to the stretchable substrate 10 in both the first region 25 and the second region 26. More specifically, the stretchable wiring 20 and the stretchable substrate 10 are preferably in close contact with each other so as to be in contact with each other on both a raised surface 25a of the first region where a part of the wiring main surface is raised and a surface 26a of the second region. By this, effects of increase in a joint area between the stretchable substrate 10 and the stretchable wiring 20 and improvement in adhesion by the anchor effect can be more suitably obtained.

As described above, the stretchable wiring 20 of the stretchable device 100 of the present disclosure may be able to improve strength of the wiring 20 while suitably maintaining stretchability. For this reason, the structure of the stretchable wiring 20 described in the present description may be suitably employed not only for the stretchable wiring 20 existing inside the laminated body 50 in which both main surfaces (21 and 23) of the wiring 20 are covered with the stretchable substrate 10, but also for the stretchable wiring 20 provided on an outermost surface 50a of the laminated body in which one of the wiring main surfaces does not face the stretchable substrate 10 (see FIG. 8). Similarly, also in a stretchable device having a single layer structure, by employing the structure of the stretchable wiring of the present disclosure, a stretchable device more suitable in terms of strength and stretchability may be provided.

Since a part of a wiring main surface is raised as described above, the first region 25 that is a raised region and the second region 26 that is another region may extend with different heights in the lamination direction X in sectional view. By this, a step structure may be provided on a wiring main surface by the first region 25 and the second region 26. More specifically, a raised surface of the first region 25 may be located at height different from that of a surface of the second region 26 in the lamination direction X, and by this, a step structure by the first region 25 and the second region 26 may be provided.

By joining the stretchable substrate 10 and the stretchable wiring 20 in such a step structure, the stretchable wiring 20 can be engaged so as to bite into the stretchable substrate 10. By such biting, the anchor effect can be more suitably applied in the joining between the stretchable substrate 10 and the stretchable wiring 20, so that the peeling resistance between the substrate 10 and the wiring 20 may be improved.

In sectional view, the thickness T1 of the stretchable wiring in the first region may be, for example, 105% or more, preferably 110% or more, and more preferably 125% or more of the thickness T2 of the stretchable wiring in the second region (see FIG. 6). Further, when emphasis is placed on stretchability of the stretchable wiring 20, the thickness T1 of the stretchable wiring in the first region may be, for example, 200% or less of the thickness T2 of the stretchable wiring in the second region, and is preferably 180% or less, more preferably 150% or less. When a difference in thickness of the stretchable wiring 20 between the first region 25 and the second region 26 falls within the above-described range, a stretchable device more suitable in terms of reliability and stretchability may be provided.

Specifically, in sectional view, the thickness T1 of the stretchable wiring in the first region may be, for example, 1 μm or more larger, preferably 4.5 μm or more larger, and more preferably 5 μm or more larger than the thickness T2 of the stretchable wiring in the second region. Further, when emphasis is placed on stretchability of the stretchable wiring 20, a difference in thickness between the thickness T1 of the stretchable wiring in the first region and the thickness T2 of the stretchable wiring in the second region may be, for example, 20 μm or less, and is preferably 10 m or less. When a difference in thickness of the stretchable wiring 20 between the first region 25 and the second region 26 falls within the above-described range, a stretchable device more suitable in terms of reliability and stretchability may be provided.

Further, as described later, in a case where a plurality of the stretchable wirings 20 are provided inside the laminated body 50 and at least a part of the stretchable wirings 20 has an overlapping portion when viewed from the lamination direction X, a plurality of the stretchable wirings 20 may be insulated from each other by arranging the stretchable substrate 10 between the wirings 20. That is, the stretchable substrate 10 interposed between a plurality of the stretchable wirings 20 may function as an insulator. At that time, by sufficiently securing thickness of the stretchable substrate 10, also in a state where thickness of the stretchable substrate 10 is relatively reduced as the stretchable device is stretched, breakage of the stretchable substrate 10 and dielectric breakdown caused by the breakage are more suitably suppressed. By this, a stretchable device more suitable in terms of connection reliability and durability may be provided.

In sectional view, thickness T3 of a stretchable substrate facing the first region 25 is not particularly limited as long as insulating property between layers can be secured by the stretchable substrate 10. That is, the thickness T3 of the stretchable substrate is not particularly limited as long as contact between conductive members such as the stretchable wiring 20 laminated with the stretchable substrates 10 interposed therebetween and an electrode (not illustrated) is prevented and the conductive members are insulated from each other. For example, while thickness of the stretchable substrate 10 may be reduced at the time of stretching, the thickness T3 of the stretchable substrate may be 5 μm or more when emphasis is placed on securing insulating property at the time of stretching of the stretchable device. On the other hand, when the thickness T3 of the stretchable substrate located between wirings is too large, there is a possibility that stretchability of the stretchable device and adhesion to an adherend are poor. When emphasis is placed on stretchability of the stretchable device and adhesion of the stretchable device to an adherend, the thickness T3 of the stretchable substrate facing the first region 25 may be, for example, 500 μm or less.

In a preferred aspect, in sectional view, the thickness T3 of the stretchable substrate facing a wiring main surface including the raised region 25 is larger than the thickness T1 of the stretchable wiring in the raised region 25. In other words, the thickness T1 of the stretchable wiring in the raised region 25 is preferably smaller than the thickness T3 of the stretchable substrate adjacent to the wiring main surface including the raised region 25. The stretchable substrate 10 of a portion facing the first region 25, which is a raised region, is more likely to receive stress from the stretchable wiring 20 than a portion facing the second region 26 that is not raised. For this reason, in some cases, the stretchable substrate 10 may be easily broken when the stretchable device is repeatedly elongated. In view of the above, by sufficiently securing thickness of the stretchable substrate 10, stress that may be applied to the stretchable substrate 10 by the stretchable wiring 20 in the raised region 25 may be suitably alleviated. By this, breakage of the stretchable substrate 10 may be able to be more suitably suppressed.

In sectional view, the thickness T3 of the stretchable substrate facing the first region 25 may be, for example, 110% or more, or 115% or more of the thickness T1 of the stretchable wiring in the first region 25, and is preferably 120% or more. On the other hand, when the thickness T3 of the stretchable substrate is too large, there is a possibility that stretchability of the stretchable device and adhesion to an adherend are poor. When emphasis is placed on the stretchability of the stretchable device and adhesion to an adherend, the thickness T3 of the stretchable substrate facing the first region 25 may be, for example, 200% or less, or 180% or less of the thickness T1 of the stretchable wiring in the first region 25, and is preferably 150% or less. When a difference in thickness between the stretchable wiring 20 in the first region 25 and the stretchable substrate 10 falls within the above-described range, a stretchable device more suitable in terms of reliability and stretchability may be provided.

Various dimensions such as thickness of the stretchable substrate 10 and the stretchable wiring 20 in the first region 25 and the second region 26 are measured by cutting the stretchable device along the thickness direction and analyzing a section of the stretchable device. For example, measurement can be performed using a three-dimensional measuring machine (for example, QV series manufactured by Mitutoyo Corporation), a microscope (for example, VHX series manufactured by KEYENCE CORPORATION), or the like.

The stretchable wiring 20 may include a plurality of the first regions 25. More specifically, two or more of the first regions 25 may be provided on one wiring main surface. Additionally or alternatively, as described later, at least one of the first regions 25 may be provided on each of two wiring main surfaces facing each other in the lamination direction X. A plurality of the first regions 25 do not necessarily have to be raised at the same height in sectional view, and may be raised at different heights. Further, the sectional view shapes may also be different from each other. When a plurality of the first regions are provided and thicknesses of the first regions are different from each other, a portion having a largest thickness is defined as the thickness T1 of the first region.

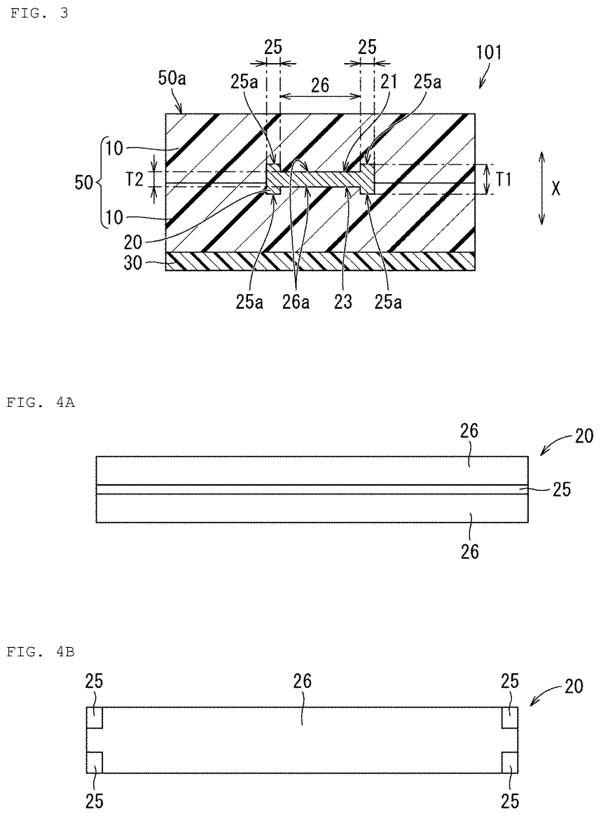

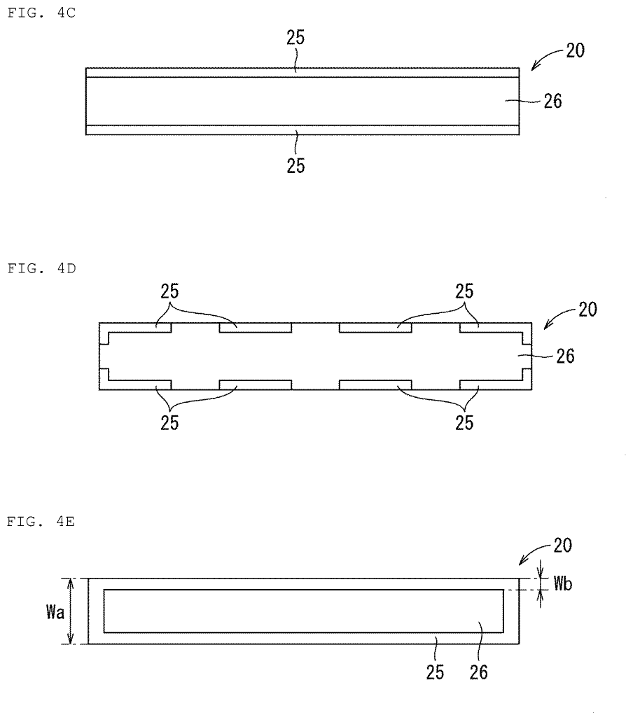

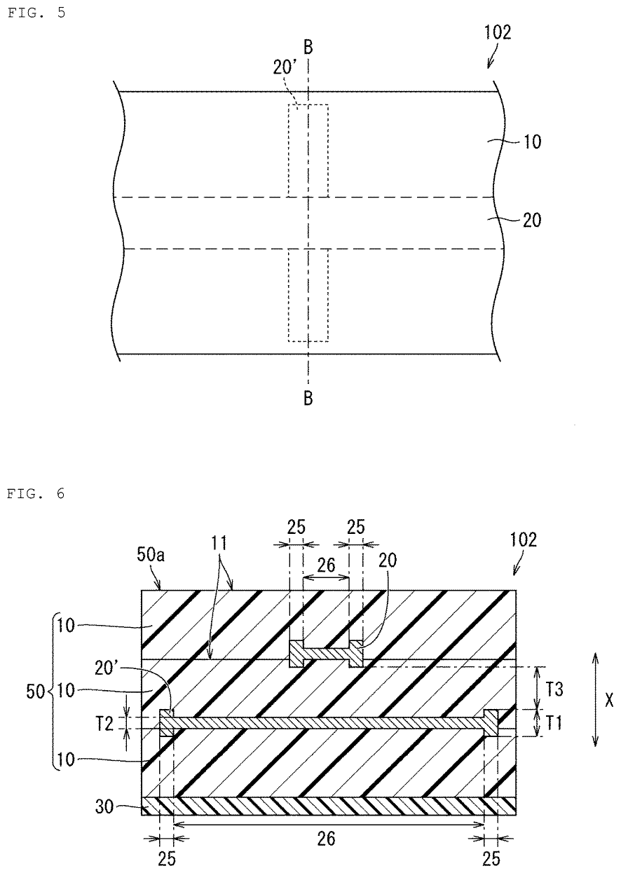

FIGS. 4A to 4E are plan views illustrating various variations of the stretchable wiring 20 included in the stretchable device of the first embodiment. As illustrated, the raised region 25 may be formed at any position on a wiring main surface of the stretchable wiring 20 facing the main surface 11 of the stretchable substrate. For example, the raised region 25 may be arranged so as to extend to the center of the stretchable wiring 20 (FIG. 4A). In such a structure, in sectional view, a wiring main surface may have a structure including the first region 25 and two of the second regions 26 on both sides of the first region 25.

In a preferred embodiment, the raised region 25 is located at a peripheral edge of the stretchable wiring 20 when viewed from the lamination direction X of the stretchable substrate 10 (FIGS. 4B to 4E). For example, the raised region 25 may extend so as to be located at least at a peripheral edge of the stretchable wiring 20. In other words, a wiring main surface may include a region where a part of the wiring main surface is raised, the region including at least a peripheral edge portion. In one embodiment, in a case where the stretchable wiring 20 includes a wiring side surface (or a wiring end surface) connecting the first wiring main surface 21 and the second wiring main surface 23, the raised region 25 may be provided so as to extend across the wiring side surface. That is, the raised region 25 may be formed so as to be continuous with the wiring side surface.

Note that the “peripheral edge of the stretchable wiring” in the present description means an outer edge or a contour portion of the stretchable wiring 20 as viewed from the lamination direction X of the stretchable substrate. Delamination between the stretchable wiring 20 and the stretchable substrate 10 and/or a crack in the stretchable wiring 20 are likely to occur at a peripheral edge of the stretchable wiring 20. For this reason, by providing the raised region 25 at the peripheral edge and increasing thickness of a part of the stretchable wiring 20, a more reliable stretchable device in which occurrence of disconnection and delamination is suitably suppressed may be provided.

Further, the raised region 25 is more preferably provided so as to be located at least at a corner portion of the stretchable wiring 20 (FIG. 4B). The corner portion means, for example, a portion where at least two sides defining a contour of the stretchable wiring 20 are connected, and also includes a corner having a curved (for example, a circular arc) shape. At such a corner portion, stress is likely to be concentrated in the stretchable wiring 20, and is likely to be a starting point of disconnection and delamination of the stretchable wiring 20. For this reason, by providing the raised region 25 at a corner portion of the stretchable wiring 20, occurrence of disconnection and delamination of the stretchable wiring 20 can be more suitably suppressed.

As another variation, the raised region 25 may extend along a periphery of the stretchable wiring 20. Further, the stretchable wiring 20 may include a plurality of the raised regions 25 on one wiring main surface. For example, as viewed in the lamination direction X, the stretchable wiring 20 may include two of the raised regions 25 extending along a peripheral edge in a longitudinal direction of the stretchable wiring 20 (FIG. 4C). Alternatively, when viewed from the lamination direction, the raised region 25 may extend along a peripheral edge of the stretchable wiring 20 so as to surround a wiring main surface of the stretchable wiring 20 in a frame shape (FIGS. 4D and 4E). That is, as viewed from the lamination direction X, the stretchable wiring 20 may include the raised region 25 formed in a frame shape along a contour of the stretchable wiring 20. Specifically, the stretchable wiring 20 may include the first region 25 (that is, the raised region) extending along a peripheral edge of the stretchable wiring 20 and the second region 26 surrounded by the first region 25. In such a structure, the stretchable wiring 20 may have a structure in which thickness is large at a peripheral portion and thickness is small at a central portion. By this, it is possible to realize a more reliable stretchable device capable of suppressing disconnection and/or delamination.

Note that the raised region 25 may be formed intermittently as illustrated in FIG. 4D, or may be formed continuously as illustrated in FIG. 4E.

In a case where the raised region 25 is located at a peripheral edge of the stretchable wiring 20 as illustrated in FIGS. 4C to 4E, a width dimension Wb of the raised region 25 is, for example, larger than 0%, preferably 10% or more of a width dimension Wa of the stretchable wiring in sectional view (see FIG. 4E). Further, when emphasis is placed on stretchability of the stretchable wiring, the width dimension Wb of the raised region 25 may be, for example, 30% or less of the width dimension Wa of the stretchable wiring, and is preferably 25% or less. When the width dimension of the raised region 25 is in the above-described range, a more reliable stretchable device capable of suitably suppressing breakage of the stretchable device may be provided. In sectional view, in a case where a plurality of the raised regions 25 are provided, the raised regions 25 may have different width dimensions.

### Variation of First Embodiment

Next, a stretchable device 101 according to a variation of the first embodiment will be described. The stretchable device 101 is different from the stretchable device 100 according to the first embodiment in that the stretchable wiring 20 includes the raised region 25 on each of two wiring main surfaces (21 and 23) facing each other.

FIG. 3 is a schematic sectional view of the stretchable device according to a variation of the first embodiment. As illustrated, the stretchable wiring 20 may include the raised region 25 on each of the first wiring main surface 21 and the second wiring main surface 23 facing each other in the lamination direction X. More specifically, the stretchable wiring 20 includes at least two of the raised regions 25, one of the raised regions 25 is located on the first wiring main surface 21, and the other one of the raised regions 25 is located on the second wiring main surface 23. A plurality of the raised regions 25 arranged on the wiring main surfaces different from each other may be raised in directions different from each other along the lamination direction X of the stretchable substrate 10. According to such a structure, it can also be understood that the raised region 25 is raised toward the stretchable substrate 10 facing a wiring main surface on which the raised region 25 is located. For example, as illustrated in FIG. 3, the raised region 25 located on the first wiring main surface 21 may be raised upward along the lamination direction X, while the raised region 25 located on the second wiring main surface 23 may be raised downward along the lamination direction X.

According to such a structure, two of the stretchable substrates 10 adjacent in the lamination direction X with the stretchable wiring 20 interposed between them can be joined to a wiring main surface including the raised region 25. For this reason, it is possible to increase a joint area with the stretchable substrate 10 on both of two of the wiring main surfaces (21 and 23). Furthermore, since the anchor effect can be applied to joining of both of two of the wiring main surfaces (21 and 23) to the stretchable substrate 10, adhesion between the stretchable wiring 20 and the stretchable substrates 10 laminated with the stretchable wiring 20 interposed between them may be further improved.

Further, as described above, in the structure including the raised region 25 on each of the two wiring main surfaces (21 and 23) facing each other, the raised region 25 located on each wiring main surface may be located coaxially along the lamination direction X. That is, the raised region 25 raised on the first wiring main surface 21 and the raised region 25 raised on the second wiring main surface 23 are preferably located coaxially along the lamination direction X of the stretchable substrates. In other words, the raised region 25 raised on the first wiring main surface 21 and the raised region 25 raised on the second wiring main surface 23 preferably overlap each other when viewed from the lamination direction X. The structure as described above can further suppress breakage of the stretchable wiring,

In a preferred aspect, the raised region 25 is provided on each of the first wiring main surface 21 and the second wiring main surface 23 along a peripheral edge of the stretchable wiring 20. That is, in sectional view, the stretchable wiring 20 may include the raised region 25 on each of the first wiring main surface 21 and the second wiring main surface 23 on both end sides in a width direction. According to such a structure, in sectional view, the stretchable wiring 20 has a shape in which thickness of both end portions of the stretchable wiring 20 is larger than thickness of a central portion (a shape including what is called a substantially dog-bone shape).

By this, thickness of the stretchable wiring 20 locally increases at a position where two of the raised regions 25 are located, and strength of the stretchable wiring 20 may be able to be further improved. For this reason, it may be possible to more suitably prevent occurrence of extension and disconnection of a crack of the stretchable wiring 20. Further, by providing the raised regions 25 on both main surfaces of the stretchable wiring 20, a peripheral portion which is likely to be a starting point of peeling can be suitably adhered and joined to the stretchable substrate 10. For this reason, the above-described structure may be suitable in terms of delamination suppression in addition to suppression of occurrence of crack extension and disconnection.

As described above, in the wiring main surface including the raised region 25, the base region 26, which is a region other than the raised region 25, does not necessarily have to be a flat surface. For example, the base region 26 may be a curved surface. In such a structure, the raised region 25 may be formed by raising a part of a wiring main surface including the base region 26 having a curved surface along the lamination direction X more than the base region 26. Also in such a structure, the anchor effect acts by the raised region 25, and an effect of improving adhesion between a wiring main surface and the stretchable substrate 10 relatively joined to the wiring main surface may be achieved.

### Second Embodiment

Next, the stretchable device according to a second embodiment will be described. The stretchable device is different from the stretchable device 100 according to the first embodiment in that the laminated body 50 includes a plurality of stretchable wirings in the inside.

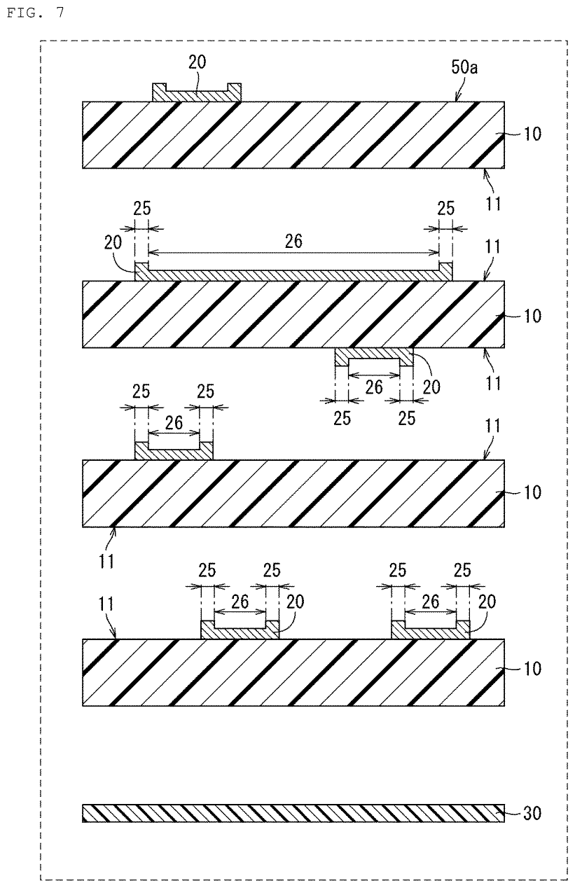

FIG. 5 is a schematic plan view of a stretchable device 102 according to the second embodiment. FIG. 6 illustrates a sectional view taken along line B-B of the stretchable device 102 illustrated in FIG. 5. As illustrated, the stretchable device may include a plurality of the stretchable wirings 20. A plurality of the stretchable wirings 20 may be arranged so as to be sandwiched between substrates of a plurality of the stretchable substrates 10 arranged in the lamination direction X and extend at different heights as viewed from the lamination direction X. This structure can also be understood as a laminated structure in which two or more layers of the stretchable substrates 10 including at least one of the stretchable wirings 20 arranged on the main surface 11 are laminated. In one embodiment, a plurality of the stretchable wirings 20 may have a portion where at least a part of the stretchable wirings 20 overlap each other with the stretchable substrate 10 interposed therebetween as viewed in the lamination direction X. In other words, the stretchable substrate 10 is preferably interposed in a portion where a plurality of the stretchable wirings 20 overlap when viewed from the lamination direction X. With such a structure, a plurality of the stretchable wirings 20 overlapping each other as viewed from the lamination direction X may be in a non-contact state with each other due to interposition of the stretchable substrate 10.

As illustrated in FIG. 5, a plurality of the stretchable wirings 20 may overlap each other at portions intersecting each other when viewed from the lamination direction X. Alternatively, a plurality of the stretchable wirings 20 may extend substantially parallel to each other while overlapping each other when viewed from the lamination direction X.

In general, the stretchable wiring 20 has higher hardness than the stretchable substrate 10. The inventor of the present application has found that, in a case where a plurality of the stretchable wirings 20 have portions in contact with each other in the lamination direction X between two of the stretchable substrates 10 adjacent to each other, the contact portion between the wirings becomes locally hard, and stress distribution is generated, so that the wiring 20 may be easily disconnected. That is, when a plurality of the stretchable wirings 20 are laminated so as to be in contact with each other, stress is likely to concentrate on the contact portion between the stretchable wirings 20, and the wiring 20 may be likely to be damaged. Further, in a contact portion between the stretchable wirings 20, hardness increases more as compared with a non-contact portion, so that an elongation rate of the stretchable device may decrease as a whole. That is, direct contact between the wirings may also affect stretchability of the stretchable device. As described above, in the stretchable device of the present disclosure, the stretchable wirings 20 indirectly overlap each other with the stretchable substrate 10 interposed therebetween. By this, local hardness unevenness is suitably alleviated, and a stretchable device more suitably having stretchability and resistance to disconnection may be provided.

In one embodiment, a plurality of the stretchable wirings 20 existing between different layers may be conductively connected to each other via vias (not illustrated). For example, in sectional view, the stretchable wirings 20 located at different heights in the lamination direction X are not in contact with each other with the stretchable substrate 10 interposed therebetween, but may be electrically conducted by a via formed in the stretchable substrate 10. Alternatively, wirings and components (electronic components such as, for example, an electrode or a sensor) located between different layers may be conductively connected to each other via a via.

Further, as long as there is no direct contact portion between the stretchable wirings 20 in the lamination direction X, a plurality of the stretchable wirings 20 may be arranged between two adjacent ones of the stretchable substrates 10. That is, as viewed from the lamination direction X, a plurality of stretchable wirings located between the same layers of two of the stretchable substrates 10 arranged adjacent to each other do not need to have a direct contact portion and may be arranged apart from each other (see FIG. 8). On the other hand, a plurality of the stretchable wirings 20 located between the same layers may be electrically connected by locally contacting each other. That is, a plurality of the stretchable wirings 20 may be separated from each other except for local contact for conduction.

Note that in a case where the stretchable device includes a plurality of the stretchable wirings 20, not all the stretchable wirings 20 necessarily have a wiring main surface having the above-described raised region 25. For example, some of the stretchable wirings 20 among a plurality of the stretchable wirings 20 does not need to include the raised region 25. In the stretchable device of the present disclosure, from the viewpoint of suitably suppressing disconnection and delamination of the stretchable wiring 20 and further improving reliability of the device, all the stretchable wirings 20 located inside the laminated body 50 preferably have a wiring main surface having the raised region 25. More preferably, all wiring main surfaces facing the stretchable substrate 10 have the raised region 25 in a part of the wiring main surfaces.

In addition to being suitable in terms of delamination resistance between the stretchable substrate 10 and the stretchable wiring 20 located on the stretchable substrate 10, the above-described configuration may be similarly suitable in terms of peel resistance from any material that may be arranged to face a wiring main surface of the stretchable wiring 20. For example, the stretchable wiring 20 having the structure of the present disclosure may be suitable in terms of peeling resistance also in joining to a resin cover layer that may be arranged on a wiring main surface or another resin layer such as an adhesive layer.

### Third Embodiment

Next, the stretchable device according to a third embodiment will be described. The stretchable device is different from the stretchable device 100 according to the first embodiment in that the stretchable wiring 20 includes a wiring main surface having predetermined surface roughness Ra.

When emphasis is placed on delamination resistance between the wiring 20 and the substrate 10, the surface roughness Ra of a wiring main surface including the raised region 25 as described above is preferably 1.8 μm or more and less than 7.7 μm, 2 μm or more and less than 7.5 μm, or 2.3 μm or more and less than 7 μm. When the surface roughness Ra is in the above-mentioned range, the stretchable substrate 10 and the stretchable wiring 20 may be more suitably joined to each other by the anchor effect exerted by unevenness of a surface of the wiring main surface.

Surface roughness of the first wiring main surface 21 (see FIG. 2) and surface roughness of the second wiring main surface 23 are not necessarily the same. Preferably, both the first wiring main surface 21 and the second wiring main surface 23 of the stretchable wiring 20 may have the surface roughness Ra in the above-described range. Furthermore, when emphasis is placed on further delamination resistance, in a case where a wiring main surface includes the first region 25 and the second region 26, the surface roughness Ra is preferably in the above-described range in both the first region 25 and the second region 26. By this, the stretchable wiring 20 can obtain the anchor effect by unevenness of a surface over the entire wiring main surface. For this reason, also when the stretchable device is expanded or contracted, the stretchable substrate 10 and the stretchable wiring 20 are not peeled off, and can be more suitably and integrally deformed.

In the present description, the surface roughness Ra means an arithmetic average roughness in accordance with JIS B0601:2001. The surface roughness Ra of a wiring main surface is an arithmetic average roughness obtained by measuring a section of the wiring main surface. The surface roughness Ra can be measured using, for example, a laser microscope.

### (Method of Manufacturing Stretchable Device)

Hereinafter, an exemplary method of manufacturing a stretchable device according to the present disclosure will be described.

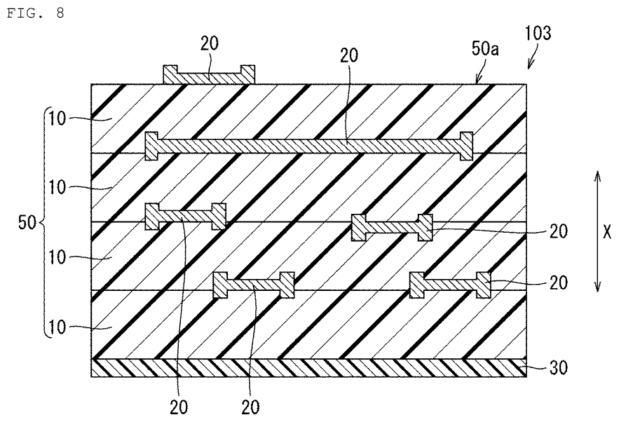

First, the stretchable substrate 10 is prepared. After the stretchable substrate 10 is prepared, the stretchable wiring 20 is formed on the main surface 11 of the stretchable substrate 10 (see FIG. 7). Formation of the stretchable wiring 20 may be performed by printing conductive paste (for example, conductive paste containing a mixture of silver and resin) on the stretchable substrate 10 by using screen printing, an inkjet method, or the like. By this, a desired circuit pattern can be obtained. At this time, by forming a wiring pattern such that a part of a wiring becomes locally thick, the first region in which a part is raised can be formed. Exemplary formation methods include two methods below.

As a first method, by providing leveling time of about five seconds or more after printing of a wiring, it is possible to form a wiring in which a part of the wiring (for example, a peripheral edge of the wiring) is thick and another part (for example, a central portion of the wiring) is thin.

As a second method, the conductive paste for the stretchable wiring described above (for example, conductive paste containing a mixture of silver and resin) is printed on a stretchable substrate by using screen printing and/or an inkjet method. At this time, a circuit pattern having large thickness in a predetermined region of the stretchable wiring can be obtained by adjusting a discharge amount of the paste in the predetermined region by a printing pattern or the like.

Further, the stretchable wiring 20 having the predetermined surface roughness Ra shown in the third embodiment can be obtained by controlling a mesh pattern in screen printing or an injection pattern of conductive paste in inkjet printing when the wiring 20 is printed on the stretchable substrate 10.

After a circuit pattern is formed on the stretchable substrate 10, the stretchable wiring 20 having thickness in a predetermined region larger than thickness of another portion is formed by drying and curing stretchable wiring conductive paste. That is, the stretchable wiring 20 having a wiring main surface including the first region 25 and the second region 26 is formed on the stretchable substrate 10. Note that printing may be performed not only on one wiring main surface but also on both surfaces of the first wiring main surface and the second wiring main surface. Further, it is also possible to mount a component on a stretchable wiring as necessary.

In a case where a plurality of the stretchable wirings 20 located on the stretchable substrates 10 different from each other are conducted, a via may be formed at a predetermined position of the stretchable substrate 10 that can be in contact with each of a plurality of the stretchable wirings 20. The via may be formed by providing a through hole at a predetermined position of the stretchable substrate and embedding a conductive material (for example, conductive paste containing a mixture of silver and resin) in the through hole. The through hole can be formed by, for example, punching or laser processing. A planar shape of the through-hole and the via is not particularly limited, and may be, for example, a perfect circle, an ellipse, or a polygon.

Subsequently, the stretchable substrate 10 having a desired circuit pattern formed by printing is stacked in the thickness direction X of the stretchable substrate 10, and pressed under application of desired temperature and desired pressure to obtain a laminated stretchable device (see FIGS. 7 and 8). As a method for improving adhesion between the stretchable wiring 20 including a raised region prepared in advance and a stretchable substrate located on both main surface sides of the stretchable wiring 20, for example, a method below is possible.

When the stretchable substrate 10 including the stretchable wiring 20 is laminated, temperature of the stretchable substrate 10 may be sufficiently raised to temperature equal to or more than glass transition temperature of resin used as the stretchable substrate 10. For example, in a case where a material of the stretchable substrate 10 is a styrene-based elastomer, heating may be performed to temperature of about 80° C. Further, since the stretchable wiring 20 made from a metal filler and resin is desirably harder than resin, heating temperature is desirably temperature equal to or less than a softening point of a material of the stretchable wiring 20. When the stretchable substrate 10 is pressed in the lamination direction X with predetermined pressure within this temperature range, the stretchable wiring 20 in the raised region 25 may also be pushed into the stretchable substrate 10 on the printing surface side. By this, in the stretchable wiring 20, each of two wiring main surfaces facing each other includes the raised region 25, and each of the raised regions 25 may be suitably engaged with the stretchable substrate 10, and it is possible to obtain further improved adhesion strength.

By the above, the stretchable device according to the present disclosure can be produced.

### EXAMPLES

Hereinafter, Examples will be described.

### [Evaluation of Delamination Resistance of First Embodiment (Stretchable Device Including Raised Region)]

### (1) Preparation of Sample

Examples 1 to 6 and Comparative Examples 1 to 2 are samples formed by varying thickness differences between the second region and the first region raised with respect to the second region on a wiring main surface facing a stretchable substrate in the stretchable device described above. Note that, in all samples in Examples, a planar shape of a wiring main surface in sectional view is as illustrated in FIG. 1, and a sectional shape is as illustrated in FIG. 3. That is, in this evaluation, a stretchable wiring including the first region along a peripheral edge of a wiring main surface on both sides of the wiring main surface and the second region in a central portion surrounded by the first region in sectional view was employed.

As a material of the stretchable wiring, composite paste of silver and acrylic resin was used. A stretchable wiring having width of 2 mm and length of 90 mm was printed on one stretchable substrate (styrene-based elastomer, 100 mm×70 mm×40 μm) by using a screen printing method. In the samples of Examples 1 to 6, the stretchable wiring was printed so that thickness of the wiring in a region of width of 200 μm increased along a peripheral edge of the stretchable wiring. After the above, the stretchable substrate was laminated and pressed at predetermined pressure (1 MPa) to obtain a stretchable device.

### (2) Measurement of Sample

Each sample was measured by a method below. Note that all measurements were performed at room temperature (about 25° C.).

### (2-1) Measurement of Thickness

Thickness of each region of the stretchable wiring was measured by cutting the prepared stretchable device along the lamination direction and measuring a section of the stretchable device by using a microscope (For example, VHX series manufactured by KEYENCE CORPORATION).

### (2-2) Measurement of Peeling Elongation Rate (Delamination Resistance)

A tensile test was performed on the produced stretchable device. Specifically, both ends of the stretchable device were sandwiched using a tensile tester, the stretchable device was elongated along a longitudinal direction of the stretchable wiring at a speed of 36 mm/min, and an elongation rate (peeling elongation rate) at a time point at which peeling occurred between the stretchable substrate and the stretchable wiring was recorded.

A measurement result in each sample of Examples 1 to 6 and Comparative Examples 1 to 2 is shown in Table 1. Note that, in the table, “Thickness difference” represents a value obtained by subtracting a value of thickness of the second region from a value of thickness of the first region.

TABLE 1

| | First region | Second region | Thickness | Peeling |
|---|---|---|---|---|
| | thickness | thickness | difference | elongation rate |
| | (μm) | (μm) | (μm) | (%) |
| Comparative | 31 | 29 | 2 | 68 |
| Example 1 | | | | |
| Comparative | 32 | 28 | 4 | 62 |
| Example 2 | | | | |
| Example 1 | 31 | 25 | 6 | 120 |
| Example 2 | 36 | 30 | 6 | 129 |
| Example 3 | 34 | 26 | 8 | 143 |
| Example 4 | 29 | 19 | 10 | 135 |
| Example 5 | 42 | 30 | 12 | 158 |
| Example 6 | 51 | 32 | 19 | 122 |

According to the above result, in the stretchable device including a stretchable wiring having a relatively small thickness difference (4 μm or less), peeling elongation rate of about 60% to 70% was exhibited, and the result that the stretchable wiring and the stretchable substrate can be elongated integrally to some extent with elongation of the stretchable device was obtained. Furthermore, the stretchable device of Examples 1 to 6 having a thickness difference of 5 μm or more exhibited a high peeling elongation rate of 120% or more. From this, a peeling elongation rate of the stretchable device can obviously be greatly improved by the first region (raised region) provided on the wiring main surface.

Further, when the stretchable wiring of the elongated sample was checked with a stereo microscope (or an electron microscope or an X-ray transmission device), no crack was confirmed in the stretchable wiring. Therefore, according to the structure of the present disclosure, a stretchable device having excellent crack resistance may be provided also in a case where the stretchable device is elongated to an elongation rate of 120% to 160%.

### [Evaluation of Delamination Resistance and Fracture Resistance of Second Embodiment (Mode Including Stretchable Substrate Interposed Between Stretchable Wirings)]

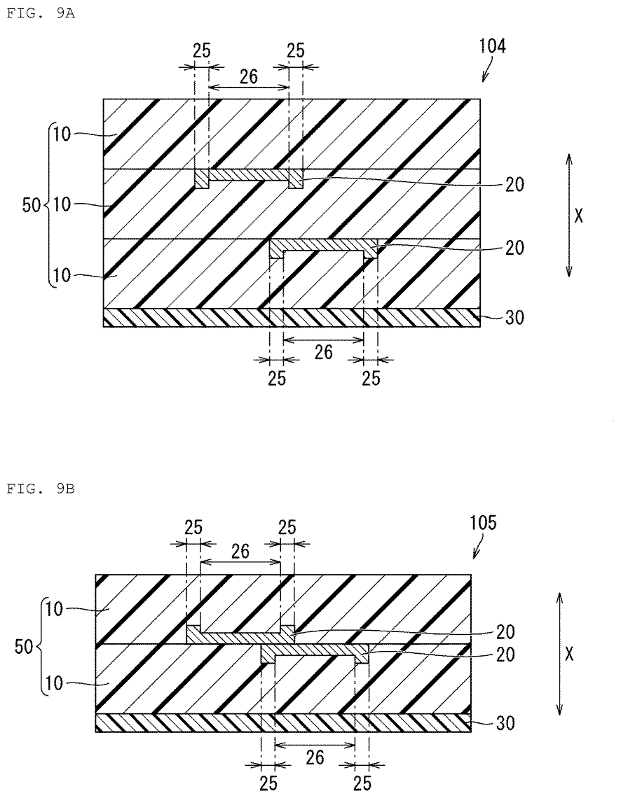

A sample of the stretchable device was prepared in the same manner to the evaluation according to the first embodiment, and a peeling elongation rate and elongation at break of the wiring were evaluated. In the example, a sample in which a plurality of the stretchable wirings 20 were arranged to overlap each other with the stretchable substrate 10 interposed therebetween was used (FIG. 9A). On the other hand, in the comparative example, a sample in which a plurality of the stretchable wirings 20 were arranged so as to directly overlap each other in the lamination direction X between the stretchable substrates 10 was used (FIG. 9B). An evaluation result is shown in Table 2.

TABLE 2

| | Peeling elongation rate | Elongation at break of wiring |
|---|---|---|
| | (%) | (%) |
| Comparative | 104 | 45 |
| Example 3 | | |
| Example 7 | 112 | 63 |

From the above result, in the stretchable device of Comparative Example 3 in which a plurality of stretchable wirings were arranged so as to directly overlap each other and the stretchable device of Example 7 in which the stretchable substrate was interposed, similar values were obtained in peeling elongation rate. On the other hand, in elongation at break of a wiring, a result showing a value 1.4 times that of Comparative Example 3 was obtained in the stretchable device of Example 7. Therefore, it was found that by interposing a stretchable substrate so that a plurality of stretchable wirings do not directly overlap each other in the lamination direction, a bias in stress distribution in an overlapping portion of the stretchable wirings is suitably alleviated, and breakage of the wiring at the time of elongation of the stretchable device can be suitably suppressed. That is, according to the present disclosure, a stretchable device having high connection reliability, which is more suitable for fracture resistance of a wiring at the time of elongation of the stretchable device, may be provided.

### [Evaluation of Delamination Resistance and Fracture Resistance of Third Embodiment (Mode Having Predetermined Surface Roughness Ra)]

A sample was prepared in the same manner to that in Comparative Example 1 in the evaluation of the first embodiment except that the surface roughness Ra on the first wiring main surface of the stretchable wiring was changed. The surface roughness Ra was adjusted by changing a mesh pattern and a printing condition in screen printing.

### (2) Measurement of Sample

For each sample, the surface roughness Ra of a wiring main surface was measured. Specifically, the stretchable device was cut along a lamination direction, and a section was observed using a laser microscope to measure the arithmetic average surface roughness Ra of the second region on the first wiring main surface of a stretchable wiring. Furthermore, a peeling elongation rate and elongation at break of a wiring were each measured by a tensile test. A measurement result is shown in Table 3.

TABLE 3

| | Surface | Peeling | Elongation at |
|---|---|---|---|
| | roughness Ra | elongation rate | break of wiring |
| | (μm) | (%) | (%) |
| Comparative | 0.9 | 82 | 60 |
| Example 4 | | | |
| Comparative | 1.7 | 73 | 58 |
| Example 5 | | | |
| Example 8 | 2.3 | 114 | 60 |
| Example 9 | 2.6 | 129 | 68 |
| Example 10 | 4.5 | 120 | 60 |
| Comparative | 7.9 | 147 | 35 |
| Example 6 | | | |

From the result described above, a result in which, in a wiring main surface having the raised region, as a value of the surface roughness Ra of the wiring main surface increases, a peeling elongation rate improves, was obtained. That is, adhesion between a stretchable substrate and a stretchable wiring is improved by the anchor effect as a wiring main surface is a more roughened surface. Therefore, according to the present disclosure, a more reliable stretchable device which is more suitable in peeling resistance between a substrate and a wiring at the time of elongation of the stretchable device may be provided. On the other hand, the stretchable device of Comparative Example 6 having the surface roughness Ra of 7.9 μm exhibited a high peeling elongation rate, but exhibited a low value in elongation at break of a wiring. This is considered to be because a wiring main surface was excessively roughened, and strength of the wiring itself decreased.

Although the embodiments of the present disclosure are described above, typical examples are only illustrated. Those skilled in the art will easily understand that the present disclosure is not limited to this, and various aspects are conceivable within a scope that does not alter the gist of the present disclosure.

### DESCRIPTION OF REFERENCE SYMBOLS

100, 101 to 105: Stretchable device
10: Stretchable substrate
11: Main surface
20: Stretchable wiring
21: First wiring main surface
23: Second wiring main surface
25: First region (raised region)
25a: Raised surface
26: Second region
30: Adhesive layer
50: Laminated body
X: Thickness direction of stretchable substrate

1. A stretchable device, comprising:
a laminated body comprising a plurality of stretchable substrates; and
a stretchable wiring arranged inside the laminated body, wherein
the stretchable wiring includes two wiring main surfaces facing each other in a lamination direction of the stretchable substrate,
at least one of the wiring main surfaces includes a first region and a second region in a sectional view of the stretchable device, and
the first region is a region in which a part of the wiring main surface is raised in the lamination direction more than that of the second region.

2. The stretchable device according to claim 1, wherein a thickness of the stretchable wiring in the first region is larger than a thickness of the stretchable wiring in the second region in the sectional view.

3. The stretchable device according to claim 1, wherein the first region is at a peripheral edge of the stretchable wiring when viewed in the lamination direction.

4. The stretchable device according to claim 1, wherein the first region is at least at a corner portion of the stretchable wiring when viewed in the lamination direction.

5. The stretchable device according to claim 3, wherein the first region extends along the peripheral edge of the stretchable wiring when viewed in the lamination direction.

6. The stretchable device according to claim 1, wherein the first region extends along a periphery of the stretchable wiring when viewed in the lamination direction.

7. The stretchable device according to claim 1, wherein
each of the two wiring main surfaces has the first region, and
in the sectional view, the first region on a first of the two wiring main surfaces and the first region on the second of the two wiring main surfaces are raised in different directions along the lamination direction of the stretchable substrate.

8. The stretchable device according to claim 7, wherein in the sectional view, the first region on the first of the two wiring main surfaces and the first region on the second of the two wiring main surfaces are coaxial along the lamination direction of the stretchable substrate.

9. The stretchable device according to claim 1, wherein the stretchable wiring is engaged with the stretchable substrate in the first region.

10. The stretchable device according to claim 1, wherein the second region is a non-raised region in the sectional view.

11. The stretchable device according to claim 1, wherein the first region and the second region define a step structure on the wiring main surface in the sectional view.

12. The stretchable device of claim 1, wherein the first region is in contact with adjacent stretchable substrates among the plurality of stretchable substrates.

13. The stretchable device according to claim 1, wherein a thickness of the stretchable wiring in the first region is smaller than a thickness of the stretchable substrate adjacent to the first region in the sectional view.

14. The stretchable device according to claim 1, wherein
the stretchable wiring is a plurality of stretchable wirings,
the plurality of stretchable wirings are arranged between the plurality of stretchable substrates in the lamination direction, and
the plurality of stretchable wirings are positioned so as to have a portion where the stretchable wirings overlap each other at least in part with the stretchable substrate interposed therebetween when viewed in the lamination direction.

15. The stretchable device according to claim 1, wherein
the stretchable wiring is a plurality of stretchable wirings,
the plurality of stretchable wirings are arranged between the plurality of stretchable substrates in the lamination direction, and
the plurality of stretchable wirings are arranged so as to be in a non-contact state with each other in the lamination direction.

16. The stretchable device according to claim 1, further comprising a second stretchable wiring on an outermost surface of the laminated body.

17. The stretchable device according to claim 1, wherein a thickness of the stretchable wiring in the first region is larger than a thickness of the stretchable wiring in the second region by 5 μm or more in the sectional view.

18. The stretchable device according to claim 1, wherein a surface roughness of the wiring main surface of the stretchable wiring is 2 μm or more and less than 7.5 μm.

19. The stretchable device according to claim 1, wherein a thickness of the stretchable wiring in the first region is 105% to 200% of a thickness of the stretchable wiring in the second region in the sectional view.
